(19) United States
(12) Patent Application Publication
(10) Pub. No.: US 2012/0288984 A1
(43) Pub. Date: Nov. 15, 2012

(54) Method for operating a vacuum Coating apparatus

(76) Inventor: Christian WACHTENDORF, Erfurt (DE)

(21) Appl. No.: 13/420,284

(22) Filed: Mar. 14, 2012

(30) Foreign Application Priority Data
Mar. 15, 2011 (DE) 10 2011 005 557.6

(51) Int. Cl. H01L 31/18; B05D 5/12

(52) U.S. Cl. 438/87; 427/74; 257/E31.061

(57) ABSTRACT

A method for operating a vacuum coating apparatus, in particular for producing thin-film solar cells, a layer deposition step being carried out, after a coating chamber cleaning step using a cleaning gas and before a product production step, in order to apply a diffusion barrier layer onto the walls of the coating chamber.

### RELATED APPLICATION INFORMATION

The present application claims priority to and the benefit of German patent application no. 10 2011 005 557.6, which was filed in Germany on Mar. 15, 2011, the disclosure of which is incorporated herein by reference.

### FIELD OF THE INVENTION

The present invention relates to a method for operating a vacuum coating apparatus, in particular for producing thin-film solar cells, in which a coating chamber cleaning step using a cleaning gas is provided.

### BACKGROUND INFORMATION

An important recent area of application of vacuum coating apparatuses is the production of thin-film solar cells based on silicon. As a rule, a PECVD method is used for this purpose.

Thin-film solar cells are made up of p-doped and n-doped layers, as well as intrinsic layers, in varying numbers. Two typical layer constructions of a known type of a thin-film solar cell, a so-called tandem cell, are shown in FIGS. 1A and 1B.

According to FIG. 1A, a glass 10 having a transparent conductive front contact layer 9 is used as a substrate. On this there is deposited a solar cell made of amorphous silicon, made up of a p-doped layer 8, an intrinsic layer 7, and an n-doped layer 5. There then follows the deposition of a microcrystalline cell, also having a p-doped layer 4, intrinsic layer 3, and an n-doped layer 2. The solar cell is finished with a further transparent, conductive, or metallic rear contact layer 1. The individual layers can also each include a plurality of sub-layers.

The modified design shown in FIG. 1B differs from the configuration according to FIG. 1A only in the provision of an intermediate reflecting layer 6 between (lower) intrinsic layer 7 and (lower) n-doped layer 5.

The deposition takes place either completely in a single coating chamber or apparatus, or in different chambers, in which case as a rule the doped layers are separated from the intrinsic layers. After one or more coating processes it is necessary to clean the chamber walls, which have unavoidably also become coated. This is done using a gas containing fluorine. The cleaning is accomplished by fluorine radicals that bond with the silicon on the chamber wall to form gaseous SiF₄ and are then removed from the chamber through the pump line. After the cleaning, the deposition of layers containing silicon then again takes place.

A cleaning method of this type is discussed in DE 10 2006 035 596 B4,

The cleaning of the coating chamber using gas containing fluorine causes fluorine to build up on and in the walls. This residual fluorine content can be disadvantageous for the subsequent deposition of silicon solar cells, and can reduce their efficiency.

### SUMMARY OF THE INVENTION

A method is proposed having the features described herein. Useful developments of the exemplary embodiments and/or exemplary methods of the present invention are the subject matter of the descriptions herein.

In order to reduce contamination by fluorine, the deposition of an additional layer is introduced. The layer acts as a (diffusion) barrier, and is deposited after the cleaning of the chamber with gas containing fluorine and before the loading of the following substrate, also by PECVD. The layer thus covers the chamber wall, and in this way reduces the diffusion of fluorine at the gas/coating boundary surface. The content of fluorine at the surface is thus reduced, so that the content of fluorine atoms/molecules in the gas phase is reduced during the subsequent deposition of silicon.

Specifically in combination with a coating chamber cleaning as an intermediate step in the production of thin-film solar cells, the proposed layer brings about a reduced fluorine loading of the solar cell construction, reflected in a higher stabilized efficiency of the cell. However, the exemplary embodiments and/or exemplary methods of the present invention may also advantageously be used in the operation of vacuum coating apparatuses for producing other semiconductor products, and, in some cases, even beyond the field of semiconductor technology.

In the context of silicon deposition processes, specifically the production of silicon-based thin-film solar cells, useful embodiments of the present invention provide that in the layer deposition step a diffusion barrier layer having silicon, silicon oxide, and/or silicon carbide is applied.

Currently, silicon oxide may be used, which is a particularly good diffusion barrier due to its high density. In addition, it can be provided that amorphous or microcrystalline silicon, or silicon having a transition phase, is applied. This is because the deposition of amorphous or microcrystalline silicon is relatively insensitive to contamination by oxygen atoms or molecules containing oxygen. Finally, it can be provided that a layer having amorphous silicon carbide is applied.

Details and method parameters of the deposition methods for the named layers are known to those skilled in the art, and are therefore not explained in more detail here.

Usefully, the layer thickness of the diffusion barrier layer is set as a function of the layer material and of a deposition temperature, in such a way that during the intended operation of the vacuum coating apparatus the diffusion barrier layer stably adheres completely to the walls of the coating chamber. The thickness of the layer should be at least some nanometers; as the layer thickness increases, the (diffusion) blocking effect of the layer also becomes greater. Currently, a layer thickness range of between 5 nm and 500 nm is considered sensible, and layer thicknesses greater than 50 nm may be used.

The method according to the present invention is explained in more detail in the following on the basis of an exemplary embodiment.

### BRIEF DESCRIPTION OF THE DRAWINGS

FIGS. 1A and 1B show the layer constructions of thin-film solar cells of the tandem type.

FIG. 2 shows a schematic representation explaining an embodiment of the proposed method.

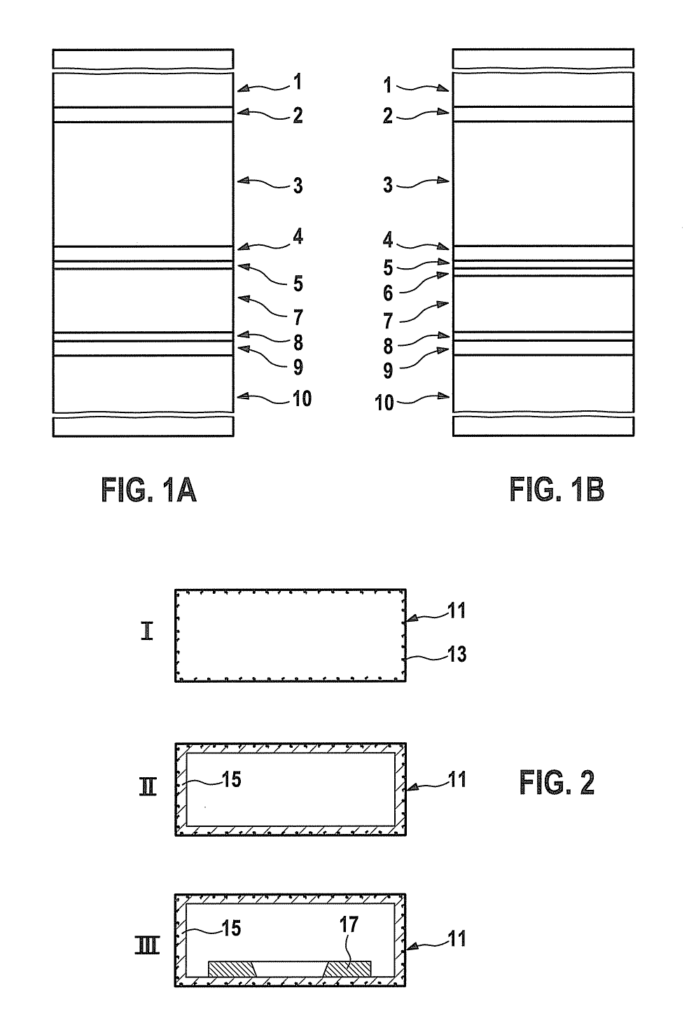

### DETAILED DESCRIPTION

FIG. 2 schematically shows a cross-section of the interior of a coating chamber 11 in three phases of an operating method according to the present invention. In phase I, after a step of cleaning the chamber with gas containing fluorine, residues 13 are situated on and in the walls. In phase II, accomplished through a PECVD deposition step without substrates, a diffusion blocking layer 15 is situated on the entire inner wall of coating chamber 11. This blocking layer completely covers all residues still present in phase I, and prevents their diffusion into the interior of the chamber.

In phase III, a substrate 17 for solar cell production is situated in coating chamber 11, which is completely lined with diffusion blocking layer 15, and this substrate is exposed to conventional coating steps. After one or more depositions of layers containing silicon, a cleaning step is again carried out using gas containing fluorine, and diffusion blocking layer 15 is removed in this step and the state of phase I is achieved.

In other respects as well, the realization of the present invention is not limited to the examples explained herein and aspects emphasized herein, but rather is equally possible in a large number of modifications that are within the scope of standard practice of those skilled in the art.

What is claimed is:

1. A method for operating a vacuum coating apparatus, for producing thin-film solar cells, the method comprising:
performing a layer deposition task, after a coating chamber cleaning task using a cleaning gas and before a product production task, to apply a diffusion barrier layer onto the walls of the coating chamber.

2. The method of claim 1, wherein a gas containing fluorine is used as cleaning gas in the coating chamber cleaning task.

3. The method of claim 1, wherein a diffusion barrier layer having at least one of a silicon, silicon oxide, silicon carbide, and silicon nitride is applied in the layer deposition task.

4. The method of claim 3, wherein one of an amorphous silicon, a microcrystalline silicon, and a silicon having a transition phase is applied in the layer deposition task.

5. The method of claim 3, wherein a layer having amorphous silicon carbide is applied in the layer deposition step.

6. The method of claim 1, wherein the layer thickness of the diffusion barrier layer is set as a function of the layer material and of a deposition temperature so that, during the intended operation of the vacuum coating apparatus, the diffusion barrier layer stably adheres completely to the walls of the coating chamber.

7. The method of claim 6, wherein the layer thickness of the diffusion barrier layer is set to a value in the range between 5 nm and 500 nm.

8. The method of claim 1, wherein the product production task following the layer deposition task includes a deposition of one of an n-doped Si layer, a p-doped Si layer, and an intrinsic Si layer of a thin-film solar cell.

9. The method of claim 6, wherein the layer thickness of the diffusion barrier layer is set to a value in the range between 50 nm and 300 nm.
